(19) United States
(12) Patent Application Publication
(10) Pub. No.: US 2023/0013291 A1
(43) Pub. Date: Jan. 19, 2023

(54) X-RAY DETECTORS WITH FRONT MOUNTED SENSOR SUBSTRATES

(71) Applicant: Varex Imaging Corporation, Salt Lake City, UT (US)

(72) Inventors: Ivan P Mollov, Mountain View, CA (US); Richard Weisfield, Los Gatos, CA (US)

(73) Assignee: Varex Imaging Corporation, Salt Lake City, UT (US)

(21) Appl. No.: 17/384,450

(22) Filed: Jul. 23, 2021

Related U.S. Application Data
(60) Provisional application No. 63/222,903, filed on Jul. 16, 2021.

(51) Int. Cl. H01L 27/146; G01T 1/20; G01T 1/24

(52) U.S. Cl. CPC H01L 27/14663; G01T 1/2018; G01T 1/244

(57) ABSTRACT

Some embodiments include an x-ray detector, comprising: a housing including a front plate; a substrate including a plurality of sensors configured to generate a two-dimensional image; and an x-ray conversion material; wherein the substrate and the x-ray conversion material are disposed within the housing and on the front plate.

Conventional x-ray detectors have sensor substrates configured to generate two-dimensional images. The sensor substrates, scintillators, or the like are mounted on support structures within a housing.

### BRIEF DESCRIPTION OF SEVERAL VIEWS OF THE DRAWINGS

FIGS. 1A-1D are block diagrams of x-ray detectors according to some embodiments.

FIG. 2 is a block diagram of an x-ray detector with an anti-scatter shield according to some embodiments.

FIGS. 3A-3D are block diagrams of x-ray detectors with printed circuit boards according to some embodiments.

FIGS. 4A-4C are block diagrams of x-ray detectors with conductive layers according to some embodiments.

FIGS. 5A and 5B are block diagram of x-ray detector with an optically absorptive layer according to some embodiments.

FIG. 6 is a block diagram of a technique of forming an x-ray detector according to some embodiments.

FIG. 7 is a block diagram of a 2D x-ray imaging system according to some embodiments.

### DETAILED DESCRIPTION

Some embodiments relate to x-ray detectors with front mounted sensor substrates. Conventional x-ray detectors include a housing enclosing an internal supporting plate. A sensor substrate, scintillator, or other components associated with the x-ray detector may be mounted on the internal supporting plate. In some embodiments, the sensor substrate, scintillator, printed circuit board (PCB), or other components may be mounted to a front plate, eliminating the internal supporting plate.

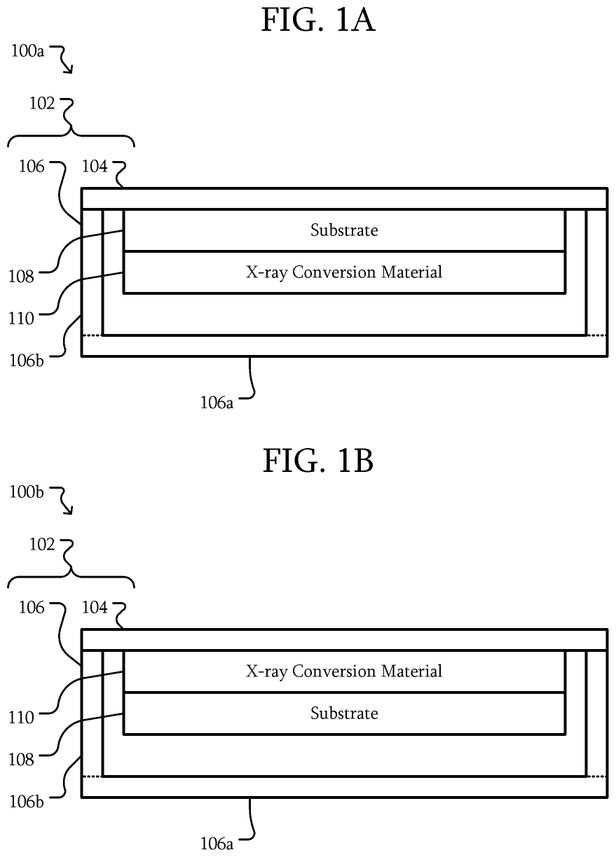

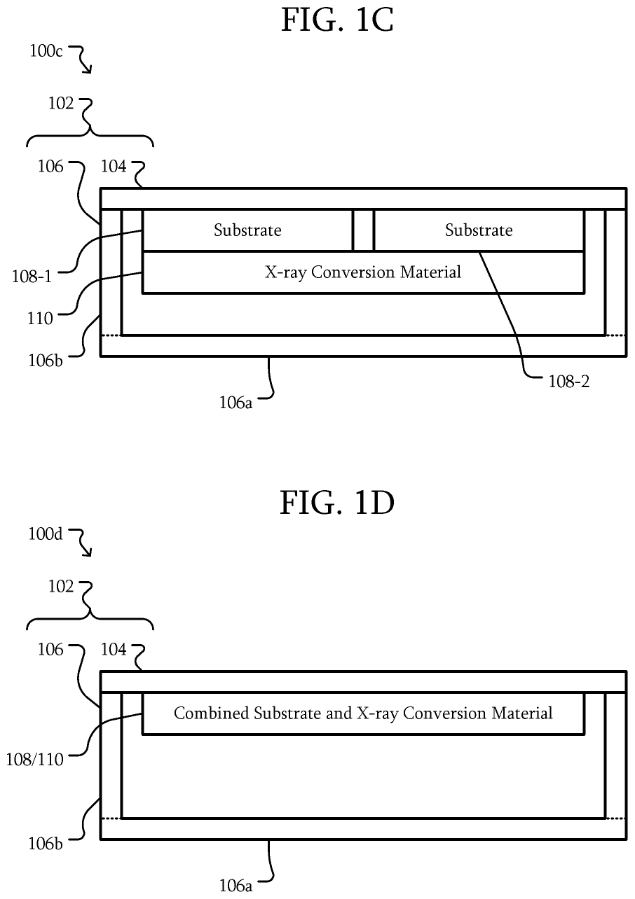

FIGS. 1A-1D are block diagrams of x-ray detectors according to some embodiments. Referring to FIG. 1A, in some embodiments, the x-ray detector 100a includes a housing 102. The housing 102 includes a front plate 104 and walls and back 106.

The front plate 104 may include a variety of materials that are substantially transparent to x-rays. For example, the front plate 104 may include metal, carbon fiber, plastic, ceramic, aluminum, or the like. The walls and back 106 of the housing 102 may include the same or a different material. For example, the walls and back 106 may include plastic, aluminum, magnesium, or the like.

The x-ray detector 100a includes a substrate 108 and an x-ray conversion material 110. The substrate 108 includes multiple sensors configured to generate a two-dimensional image. The substrate 108 may include an amorphous silicon (a-Si) complementary metal oxide semiconductors (CMOS), indium gallium zinc oxide (IGZO), or a photon counting technology, such as cadmium telluride (CdTe), cadmium zinc telluride (CdZnTe or CZT), selenium photodetectors, or the like. The substrate 108 may include plastic, glass, or other material.

The combination of the substrate 108 and the x-ray conversion material 110 may form an indirect or direct conversion sensor. For example, the x-ray conversion material 110 may include a scintillator including materials configured to convert x-ray photons into photons detectable by the sensors of the substrate 108. A scintillator may include cesium iodide (CsI), cadmium tungstate (CdWO₄), polyvinyl toluene (PVT), gadolinium oxysulfide (Gd₂O₂S; GOS; Gadox), gadolinium oxysulfide doped with terbium (Gd₂O₂S:Tb), or the like. In some embodiments, the combination of the substrate 108 and the x-ray conversion material 110 may not include a scintillator but may include the direct conversion such as CdTe, CdZnTe or CZT, mercury iodide (HgI), lead iodide (PbI), selenium photodetectors, or the like as described above.

Regardless of the type, the substrate 108 and the x-ray conversion material 110 may be disposed within the housing 102 and on or coupled to the front plate 104. The front plate 110 may structurally support the substrate 108.

The substrate 108 may be disposed on the front plate 104 in a variety of ways. In some embodiments, the substrate 108 is glued to the front plate 104. For example, an adhesive such as epoxy or room-temperature-vulcanizing (RTV) silicone may be applied on the interface between the substrate 108 and the front plate 104. In some embodiments, the adhesive may be applied to all or substantially all of the interface. The use of the adhesive may reduce or eliminate relative movement between the substrate 108 and the front plate 104. This support may improve the durability or resistance of the substrate 108 to drops, impacts, or the like. Due to the increased durability provided by the support, the substrate 108 can have a smaller thickness than conventional substrates. For example, a conventional substrate attached to an internal support may be 0.7 millimeters (mm) or greater to withstand common shocks experience by a conventional x-ray detector. In some embodiments, the substrate 108 may be 0.65 mm, 0.6 mm, 0.55 mm, 0.5 mm, or less. For example, a glass substrate can be 0.5 mm or less, and a plastic substrate can be 0.35 mm or less. In other embodiments, the substrate 108 may be supported in other ways, such as by corner guides or supports, edge guides or supports, fasteners, compression, or the like. In some embodiments, the substrate 108 may have not other support other than the attachment to the front plate by the adhesive or other support structures.

In some embodiments, the substrate 108 is disposed on the front plate and the x-ray conversion material 110 is disposed on the substrate 108. That is, the substrate 108 may be disposed between the x-ray conversion material 110 and the front plate 104. The x-ray conversion material 110 may be attached to the substrate 108 using an adhesive or other techniques similar to those used to attach the substrate 108 to the front plate 104. In other embodiments, the x-ray conversion material 110 may be deposited, evaporated, or otherwise formed on the substrate 108. In some embodiments, having the substrate 108 attached directly to the front plate 104 without a major intervening structure may improve the resistance of the substrate 108 to sheer forces experienced during a fall, impact, or the like. U.S. Pat. No. 7,122,804, titled “X-Ray Imaging Device,” which is incorporated by reference in its entirety, discloses an example of x-rays propagating through a substrate including photodiodes before propagating through a scintillator.

In some embodiment, the sensors of the substrate 108 may be disposed in the substrate on an active side. The active side may be the side that is closest to the x-ray conversion material 110.

In some embodiments, one or more of the walls and back 106 of the housing 102 maybe formed of a material different from the front plate 104. For example, one or more of the walls and back 106 may be formed of plastic. As the front plate 104 may provide structural support for the substrate 108, the walls and back 106 may be formed from materials that are less rigid, lighter, or the like. Such materials may reduce a cost and/or weight of the housing 102. In some embodiments, the walls and back 106 may be formed from separate and/or separable components. For example, the walls 106b may be separable from the back 106a as indicated by the dashed line; however, the location of the separation may be different than that illustrated.

Referring to FIG. 1B, in some embodiments, the x-ray detector 100b may be similar to the x-ray detector 100a. However, the x-ray conversion material 110 may be disposed on the front plate 104. The substrate 108 may be disposed on the x-ray conversion material 110. Accordingly, the substrate 108 is disposed on the front plate 104 by a structure including the x-ray conversion material 110. The substrate 108 and the x-ray conversion material 110 may be attached to the front plate 104 using an adhesive or other techniques similar to those used to attach the substrate 108 and the x-ray conversion material 110 to the front plate 104. In some embodiments, the efficiency of the x-ray detector 100b may be increased as the x-rays are not attenuated by the substrate 108 before conversion in the x-ray conversion material 110.

Referring to FIG. 1C, in some embodiments, the x-ray detector 100c may be similar to the x-ray detector 100a. However, the x-ray detector 100c may include multiple substrates 108. Here two substrates 108-1 and 108-2 are illustrated; however, in other embodiments, a different number of substrates 108 may be used. In some embodiments, the substrates 108 may be disposed in a two-dimensional array. In a particular example, the substrates may be CMOS substrates 108. CMOS substrates 108 may have size limitations and may be tiled to create a large effective substrate 108.

In some embodiments, a single x-ray conversion material 110 is formed across the substrates 108. However, in other embodiments, each substrate 108 may have its own x-ray conversion material 110.

Referring to FIG. 1D, the x-ray detector 100d may be similar to the x-ray detectors 100a-b described above. However, substrate 108 and the x-ray conversion material 110 may be combined. The x-ray conversion material 110 may be included in the x-ray detector 100d by being included as a layer in the substrate 108, included as part of the sensors of the substrate 108, or the like.

In the following figures, the substrate 108 and x-ray conversion material 110 may be illustrated as a single block. That single block may represent any of the combination of the substrate 108 and x-ray conversion material 110 described above.

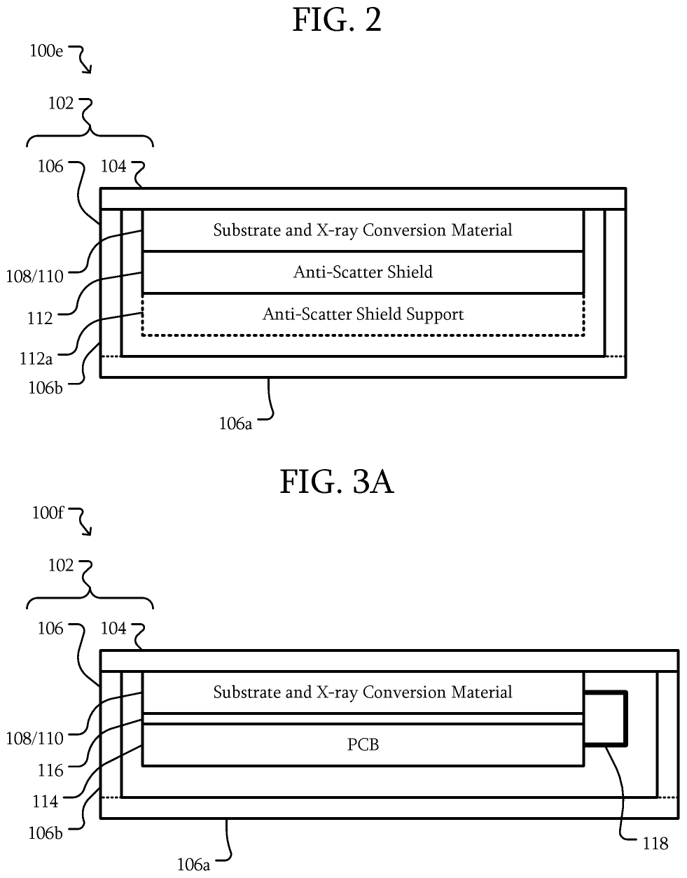

FIG. 2 is a block diagram of an x-ray detector with an anti-scatter shield according to some embodiments. In some embodiments, the x-ray detector 100e may be similar to the x-ray detector 100a-d described above. However, the x-ray detector 100e includes an anti-scatter shield 112. The substrate 108 and the x-ray conversion material 110 are disposed between the front plate 104 and the anti-scatter shield 112.

The anti-scatter shield 112 includes a material that absorbs x-rays. For example, the anti-scatter shield 112 may include lead, tungsten, or the like. Due to the anti-scatter shield 112 structures that may otherwise have scattered x-rays back into the substrate 108 may have a reduced or eliminated impact on any resulting image.

In some embodiments, the anti-scatter shield 112 may include a flat layer, a planar layer, a layer with a substantially uniform thickness, or the like. In a particular example, the anti-scatter shield 112 may include an about 0.5 millimeter (mm) to about 2 mm thick sheet. As a result, any x-rays that are not absorbed and may scatter from the anti-scatter shield 112 may scatter substantially uniformly. An effect of any resulting artifact may be reduced. An artifact (or error) is a misleading or confusing alteration in data or observation resulting from flaws in technique or equipment. Visual artifact are anomalies during visual representation of digital graphics and imagery.

The anti-scatter shield 112 may be attached to the substrate 108 and the x-ray conversion material 110 in a variety of ways. In some embodiments, the anti-scatter shield 112 is attached to the x-ray conversion material 110 with an adhesive. The anti-scatter shield 112, substrate 108, and the x-ray conversion material 110, may form a stack of materials adhered to the front plate 104. In other embodiments, the anti-scatter shield 112 may be attached to the substrate 108 when the x-ray conversion material 110 is between the substrate 108 and the front plate 104 as in FIG. 1B.

In some embodiments, the anti-scatter shield 112 may be attached to an anti-scatter shield support 112a. The anti-scatter shield support 112a may include a plate of supporting material such as plastic, aluminum, or the like. The anti-scatter shield 112 may be attached to the anti-scatter shield support 112a. The anti-scatter shield support 112a may be attached to other structural features of the housing 102 or other components of the x-ray detector 100e. In some embodiments, the anti-scatter shield 112 may not be attached to the substrate 108 or x-ray conversion material 110. Any attachment points of the anti-scatter shield support 112a, such as fasteners, or other structures that may otherwise non-uniformly scatter x-rays may be masked by the anti-scatter shield 112.

In some embodiments, regardless of how it is attached or supported, the anti-scatter shield 112 may be the structure immediately adjacent to the substrate 108 and x-ray conversion material 110. Accordingly, the anti-scatter shield 112 may mask any structures downstream along the path of incident x-rays.

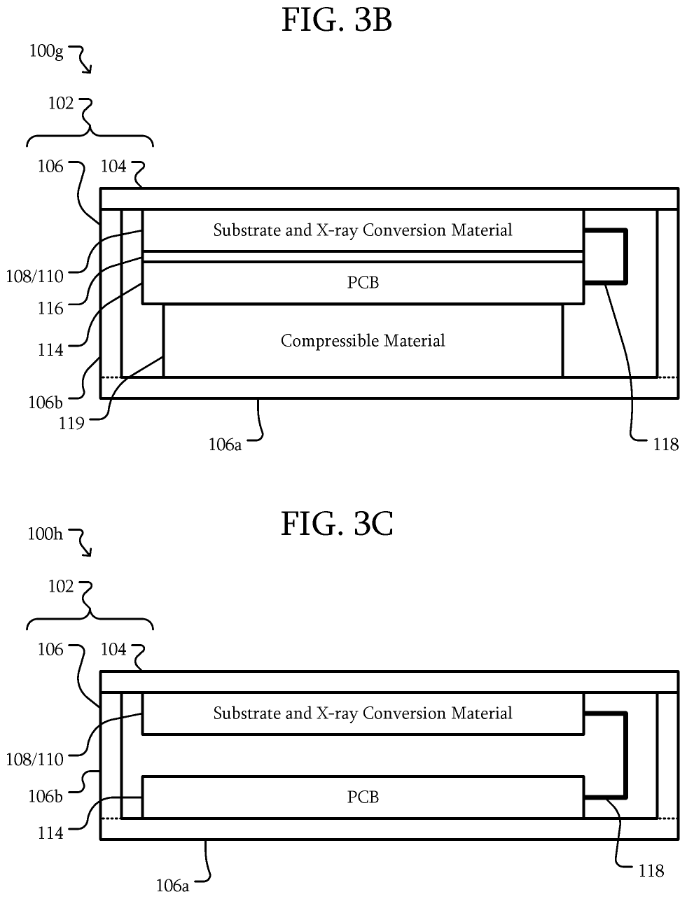

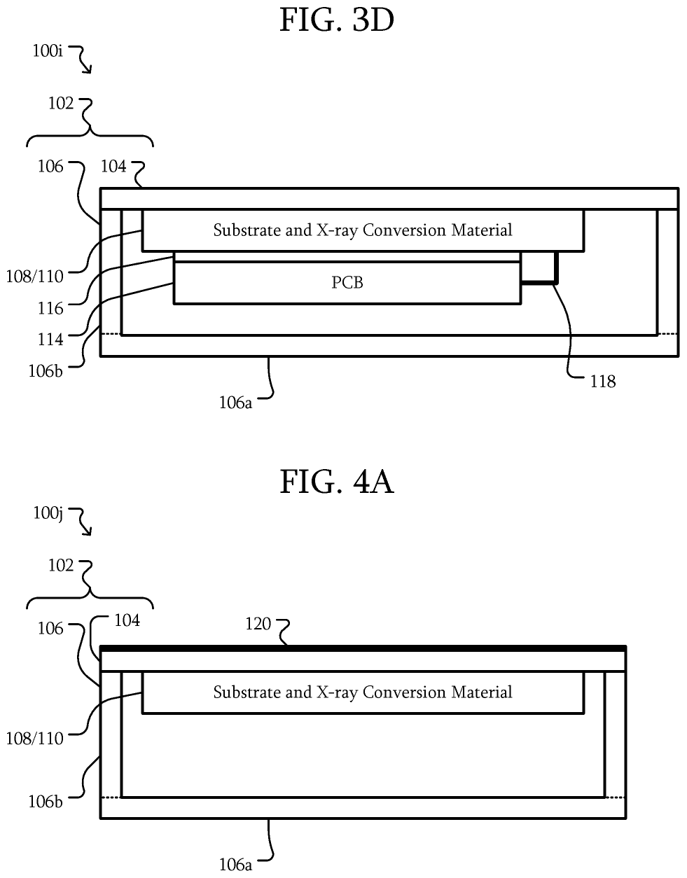

FIGS. 3A-3D are block diagrams of x-ray detectors with printed circuit boards according to some embodiments. Referring to FIG. 3A, in some embodiments, the x-ray detector 100f may be similar to the x-ray detector 100a-e. However, the x-ray detector 100f includes a printed circuit board (PCB) 114. The PCB 114 may be attached to the front plate 104. In some embodiments, the PCB 114 is attached to the front plate by the stack including the substrate 108 and x-ray conversion material 110.

In some embodiments, the PCB 114 is attached to the substrate 108 or x-ray conversion material 110 with a releasable adhesive 116. The releasable adhesive 116 may be in the form of a sheet disposed between the PCB 114 and the substrate 108 and x-ray conversion material 110. As a result, the attachment of the PCB 114 may be resistant to shear forces in the plane of the releasable adhesive 116, but still removable by applying a force in a direction perpendicular to the plane of the releasable adhesive 116.

In some embodiments, a flexible electric circuit 118 electrically couples the PCB 114 to the substrate 108. The flexible electric circuit 118 may include a flat cable, a ribbon cable, wire bonds, ribbon bonds, or the like. The flexible electric circuit 118 may include other electronic components or application-specific integrated circuits (ASICs). The flexible electric circuit 118 may be configured to allow for some movement between the PCB 114 and the substrate 108 while maintaining the electrical connection.

The PCB 114 may include various circuits such as readout circuits, amplifiers, analog to digital converters, processors, application specific integrated circuits (ASICs), or the like. The circuits may be configured to perform various operations on data received from the substrate 108. The flexible electric circuit 118 may be configured to enable the transfer of data, commands, or the like, between the substrate 108 and the PCB 114. The PCB 114 may have other electrical connections not illustrated to enable communication to systems external to the x-ray detector 100f.

Referring to FIG. 3B, the x-ray detector 100g may be similar to the x-ray detector 100f. However, the x-ray detector 100g may include a compressible material 119. The compressible material 119 may include various open or closed cell foams, springs, rubber resilient materials, or the like that may apply a resisting force when compressed.

The compressible material 119 is disposed between the PCB 114 and a side of the housing 102 opposite to the front plate 104. Here, the compressible material 119 is disposed between the PCB 114 and a back 106a of the housing 102 that is opposite to the front plate 104. However, the compressible material 119 may be disposed in different locations.

The compressible material 119 may include a single sheet or block of material. However, in other embodiments, the compressible material 119 may include multiple discrete portions, have different shapes, or the like. The compressible material 119 may help to reduce stress and/or damage on the various layers (e.g., substrate 108, x-ray conversion material 110, anti-scatter shield 112, and PCB 114) between the front plate 104 and the back 106a of the housing 102 due to shock, drops, or other movement.

Referring to FIG. 3C, the x-ray detector 100h may be similar to the x-ray detector 100a-g. However, the x-ray detector 100h may include a PCB 114 that is indirectly attached to the substrate 108 and x-ray conversion material 110. Here, the PCB 114 is attached to the back 106a of the housing 102, opposite to the front plate 104; however, the PCB 114 may be attached to other locations of the housing 102, such as the walls 106b, other structures within the housing 102 or the like. Because of the flexible electric circuit 118, the PCB 114 may move relative to the substrate 108 without losing an electrical connection.

Referring to FIG. 3D, the x-ray detector 100i may be similar to the x-ray detector 100a-h. However, the size of the PCB 114 may be smaller than the substrate 108. At least a portion of the substrate 108 may extend beyond a perimeter of the PCB 114 in plan view. That is, the PCB 114 may extend substantially in a plane. At least a portion of a projection of the substrate 108 on to that plane may be outside of the perimeter of the PCB 114 on the plane. The flexible electric circuit 118 may be attached to a surface of the substrate 108 that extends beyond that perimeter of the PCB 114. As a result, the flexible electric circuit 118 may not limit a length or width of the x-ray detector 100i. That is, another component, such as the substrate 108, may limit the minimum length or width.

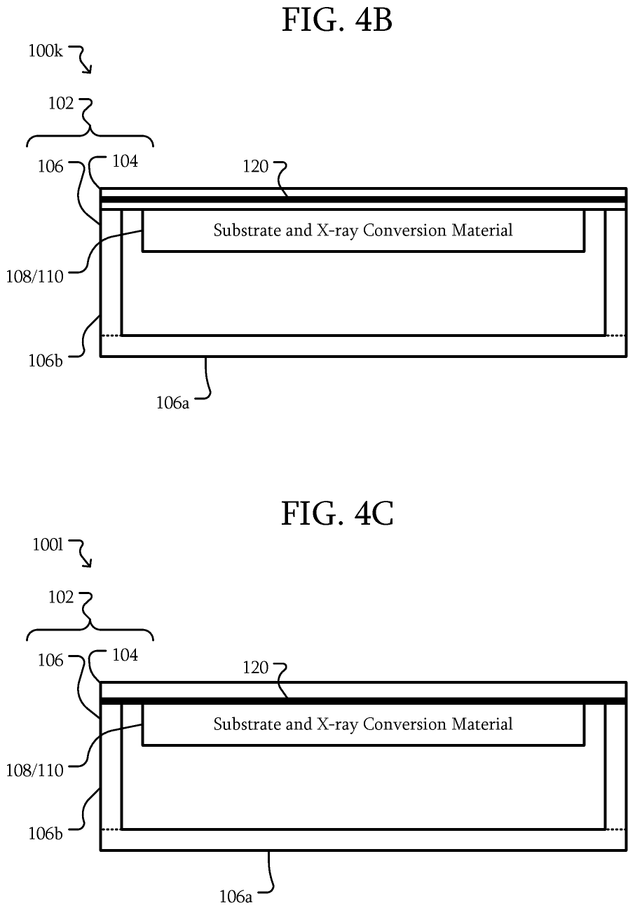

FIGS. 4A-4C are block diagrams of x-ray detectors with conductive layers according to some embodiments. Referring to FIG. 4A, in some embodiments, the x-ray detector 100j may be similar to the x-ray detector 100a-i. However, the x-ray detector 100j may include a conductive layer 120. The conductive layer 120 may be disposed on the same side of the substrate 108 as the front plate 104. In some embodiments, the conductive layer 120 is disposed on an outer surface of the front plate 104.

In some embodiments, the conductive layer 120 may be a foil formed of a conductive metal, such as aluminum, or other conductive material. In other embodiments, the conductive layer 120 may include a conductive coating such as copper paint. The conductive layer 120 may be attached to the front plate 104 and/or formed on the front plate 104 in a manner appropriate to the particular type of conductive layer 120.

The conductive layer 120 may be electrically connected to other conductive structures of the x-ray detector 100j. For example, the side and back walls 106 may be formed of a conductive material, include a conductive coating, or the like. The conductive layer 120 may be electrically connected to such conductive structures. The conductive layer 120 may cover the same area or a portion of the area of the front plate 104. For example, one or more fasteners may electrically connect the conductive layer 120 to other conductive structures. The combination of the conductive structures may form an electro-magnetic interference (EMI) shield for at least a part of the x-ray detector 100j.

Referring to FIG. 4B, in some embodiments, the x-ray detector 100k may be similar to the x-ray detector 100j. However, the conductive layer 120 may be disposed within the front plate 104. For example, the front plate 104 may include a laminated structure. The conductive layer 120 may be one of the laminated layers forming the front plate 104.

Referring to FIG. 4C, in some embodiments, the x-ray detector 100l may be similar to the x-ray detector 100k. However, the conductive layer 120 may be disposed on an inner surface of the front plate 104.

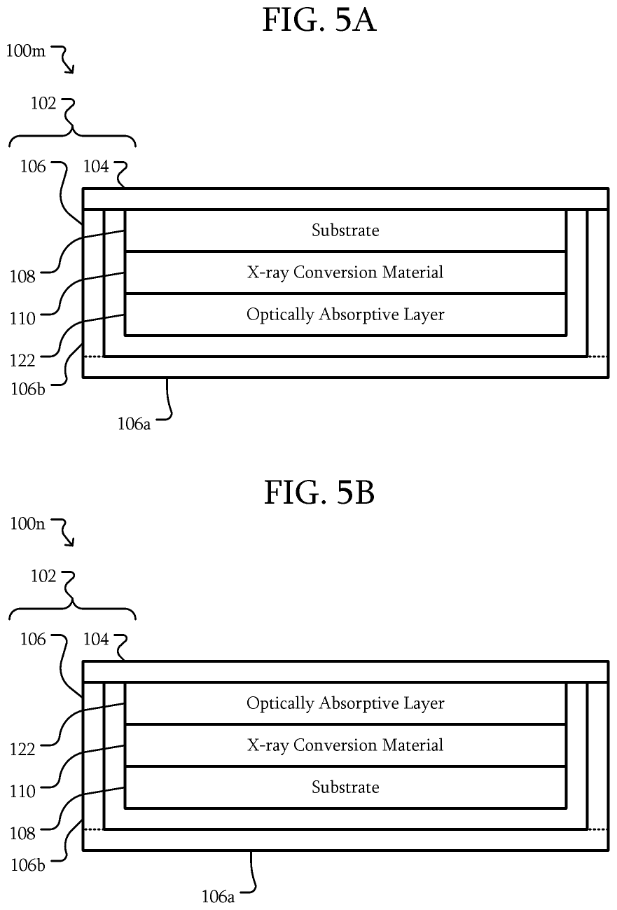

FIGS. 5A and 5B are block diagrams of x-ray detector with an optically absorptive layer according to some embodiments. The x-ray detectors 100m and 100n may be similar to the x-ray detector 100a-k. However, the x-ray detectors 100m and 100n include an optically absorptive layer 122. The optically absorptive layer 122 includes material that absorbs light generated by the x-ray conversion material 110. For example, the optically absorptive layer 122 may include black anodized aluminum. The optically absorptive layer 122 is disposed on a side of the x-ray conversion material 110 opposite to the substrate 108. Thus, the optically absorptive layer 122 may be in different positions depending on the orientation of the x-ray conversion material 110 and the substrate 108.

Light from the x-ray conversion material 110 generated by the conversion of x-rays may be directed towards structures other than the substrate 108. That light may scatter off of other structures and eventually be detected in the substrate 108. The signal detected from that light may introduce artifacts in an image. By absorbing at least some of the light in the optically absorptive layer 122, an effect of the scattered light may be reduced, reducing potential artifacts.

As illustrated in FIG. 5B, the optically absorptive layer 122 may be adjacent to the front plate 104. In some embodiments, the optically absorptive layer 122 may be a coating on or part of the front plate 104. For example, the front plate 104 may include a black anodized aluminum plate. In other embodiments, a carbon fiber front plate 104 may be black. Thus, the optically absorptive layer 122 may be integrated with the front plate 104.

In some embodiments, the conductive layer 120 of FIGS. 4A-4C may be combined with the optically absorptive layer 122. For example, a black anodized aluminum foil, or a black anodized aluminum front plate 104 may act as both the optically absorptive layer 122 and the conductive layer 120.

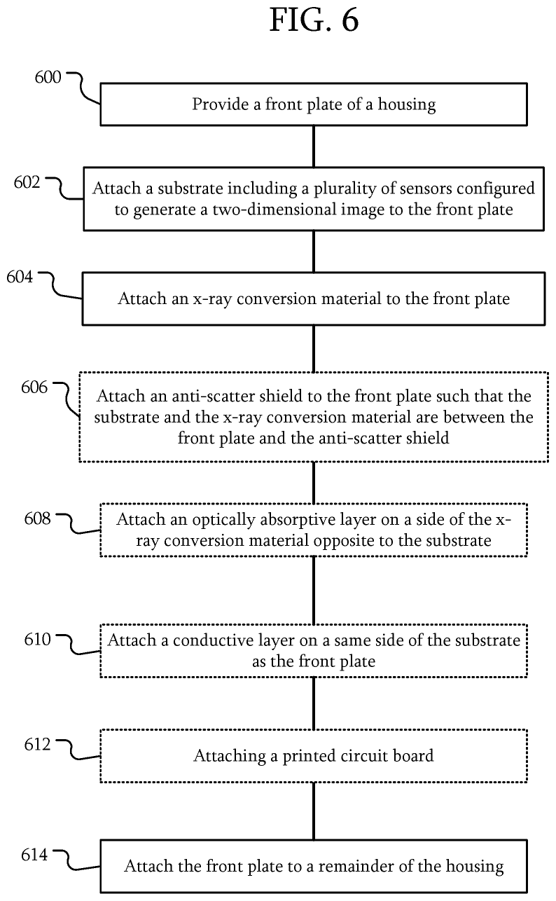

FIG. 6 is a flowchart of techniques a technique of forming an x-ray detector according to some embodiments. In some embodiments, in 600, a front plate 104 of a housing 102 is provided. In 602, a substrate 108 including a plurality of sensors configured to generate a two-dimensional image is attached to the front plate 104. In 604, an x-ray conversion material 110 is attached to the front plate 104. In some embodiments, the attachment of the substrate 108 and the x-ray conversion material 110 to the front plate in 602 and 604 may be accomplished by attaching a substrate 108 that includes the x-ray conversion material 110 as described above. In addition, depending on the sequence of operations of 602 and 604, in some embodiments, the substrate 108 may be attached to the front plate 104 by a structure including the x-ray conversion material 110 while in other embodiments, the x-ray conversion material 110 may be attached to the front plate 104 by a structure including the substrate 108. In 614, the front plate 104 is attached to a remainder of the housing 102.

In some embodiments, the front plate 104 may be placed face down. The substrate 108 and x-ray conversion material 110 may be attached to the front plate in the order described above. In some embodiments, the substrate 108 may be thinned on the front plate 104. The substrate 108 and x-ray conversion material 110 may be attached to each other and the front plate 104 by an adhesive, by depositing or forming the x-ray conversion material 110, or the like. The stack may be structurally supported by the front plate 104. Other components may be attached and the housing 102 may be closed by attaching the front plate 104 to a remainder of the housing 102 in 614.

In some embodiments, in 606, an anti-scatter shield 112 may be attached to the front plate such that the substrate 108 and the x-ray conversion material 110 are between the front plate 104 and the anti-scatter shield 112. The attachment may be performed as described above by using an adhesive to attach the anti-scatter shield 112, by attaching the anti-scatter shield support 112a, or the like.

In some embodiments, in 608, an optically absorptive layer 122 is attached on a side of the x-ray conversion material 110 opposite to the substrate 108. As described above, the optically absorptive layer 122 may be a foil that is attached, inherently part of a structure, such as a carbon-fiber plate, a black anodized aluminum front plate 104, or the like.

In some embodiments, in 610, a conductive layer is attached on a same side of the substrate as the front plate 104. As described above, the conductive layer 120 may be attached to the front plate 104. In addition, the conductive layer 120 may be attached as part of the front plate 104, part of the optically absorptive layer 122, or the like.

In some embodiments, in 612, a PCB 114 is attached. The PCB 114 may be attached to a side of the housing 102 opposite to the front plate 104, such as the back 106a. The PCB 114 may be attached to the front plate 104 such that the substrate 108 and the x-ray conversion material 110 are between the front plate 104 and the PCB 114.

Although an order of operations has been described above, in other embodiments, the order may be different. In addition, some operations may be omitted.

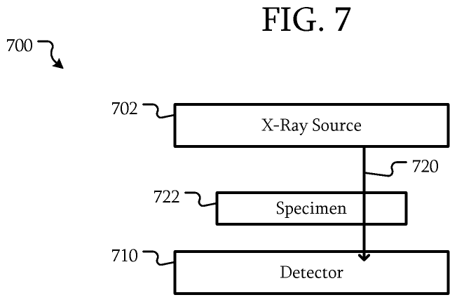

FIG. 7 is a block diagram of a 2D x-ray imaging system according to some embodiments. The 2D x-ray imaging system 700 includes an x-ray source 702 and detector 710. The x-detector 710 may include an x-ray detector 100a-100n or the like as described above. The x-ray source 702 is disposed relative to the detector 710 such that x-rays 720 may be generated to pass through a specimen 722 and detected by the detector 710. In some embodiments, the detector 710 is part of a medical imaging system. In other embodiments, the 2D x-ray imaging system 700 may include a portable vehicle scanning system as part of a cargo scanning system.

Some embodiments include an x-ray detector, comprising: a housing 102 including a front plate 104; a substrate 108 including a plurality of sensors configured to generate a two-dimensional image; and an x-ray conversion material 110; wherein the substrate 108 and the x-ray conversion material 110 are disposed within the housing 102 and on the front plate 104.

In some embodiments, the substrate 108 is disposed on the front plate 104; and the x-ray conversion material 110 is disposed on the substrate 108 or is part of the substrate 108.

In some embodiments, the x-ray conversion material 110 is disposed on the front plate 104; and the substrate 108 is disposed on the x-ray conversion material 110.

In some embodiments, the x-ray detector further comprises an anti-scatter shield 112 wherein the substrate 108 and the x-ray conversion material 110 are disposed between the front plate 104 and the anti-scatter shield 112.

In some embodiments, the x-ray detector further comprises a printed circuit board 114 attached to the front plate 104 by a structure including the substrate 108.

In some embodiments, the x-ray detector further comprises compressible material disposed between the printed circuit board 114 and a side of the housing 102 opposite to the front plate 104.

In some embodiments, the printed circuit board 114 is attached to the front plate 104 by the structure including the substrate 108 with a releasable adhesive.

In some embodiments, the x-ray detector further comprises a printed circuit board 114 disposed on a side of the housing 102 opposite to the front plate 104.

In some embodiments, the x-ray detector further comprises a printed circuit board 114; and a flexible electric circuit electrically coupling the printed circuit board 114 to the substrate 108.

In some embodiments, the substrate 108 includes a planar portion extending beyond a perimeter of the printed circuit board 114, wherein the substrate 108 is substantially planar; and the substrate 108 is electrically connected to the flexible electric circuit by the planar portion extending beyond the perimeter of the printed circuit board 114.

In some embodiments, at least one wall of the housing 102 other than the front plate 104 if formed of plastic.

In some embodiments, the x-ray detector further comprises a conductive layer 120 disposed on a same side of the substrate 108 as the front plate 104.

In some embodiments, the x-ray detector further comprises an optically absorptive layer 122 disposed on a side of the x-ray conversion material 110 opposite to the substrate 108.

Some embodiments include a method, comprising: providing a front plate 104 of a housing 102; attaching a substrate 108 including a plurality of sensors configured to generate a two-dimensional image to the front plate 104; attaching an x-ray conversion material 110 to the front plate 104; and attaching the front plate 104 to a remainder of the housing 102.

In some embodiments, the method further comprises attaching an anti-scatter shield 112 to the front plate 104 such that the substrate 108 and the x-ray conversion material 110 are between the front plate 104 and the anti-scatter shield 112.

In some embodiments, attaching the x-ray conversion material 110 to the front plate 104 comprises attaching the x-ray conversion material 110 to the substrate 108; or attaching the substrate 108 to the front plate 104 comprises attaching the substrate 108 to the x-ray conversion material 110.

In some embodiments, the method further comprises at least one of: attach an optically absorptive layer 122 on a side of the x-ray conversion material 110 opposite to the substrate 108; and attach a conductive layer 120 on a same side of the substrate 108 as the front plate 104.

In some embodiments, the method further comprises attaching a printed circuit board 114 to a side of the housing 102 opposite to the front plate 104; or attaching the printed circuit board 114 to the front plate 104 such that the substrate 108 and the x-ray conversion material 110 are between the front plate 104 and the printed circuit board 114.

Some embodiments include an x-ray detector, comprising: means for converting x-rays into a two-dimensional image; means for enclosing the means for converting the x-rays into the two-dimensional image; and means for supporting the means for converting the x-rays into the two-dimensional image on a front of the means for enclosing the means for converting the x-rays into the two-dimensional image.

Examples of the means for converting x-rays into a two-dimensional image include the substrate 108, the x-ray conversion material 110, and the PCB 114. Examples of the means for enclosing the means for converting the x-rays into the two-dimensional image include the housing 102. Examples of the means for supporting the means for converting the x-rays into the two-dimensional image on a front of the means for enclosing the means for converting the x-rays into the two-dimensional image include the front plate 104.

In some embodiments, the x-ray detector further comprises at least one of: means for reducing scatter of x-rays passing through the means for converting the x-rays into the two-dimensional image; and means for absorbing light from the means for converting the x-rays into the two-dimensional image. Examples of the means for reducing scatter of x-rays passing through the means for converting the x-rays into the two-dimensional image include the anti-scatter shield 112. Examples of means for absorbing light from the means for converting the x-rays into the two-dimensional image include the optically absorptive layer 122.

Although the structures, devices, methods, and systems have been described in accordance with particular embodiments, one of ordinary skill in the art will readily recognize that many variations to the particular embodiments are possible, and any variations should therefore be considered to be within the spirit and scope disclosed herein. Accordingly, many modifications may be made by one of ordinary skill in the art without departing from the spirit and scope of the appended claims.

The claims following this written disclosure are hereby expressly incorporated into the present written disclosure, with each claim standing on its own as a separate embodiment. This disclosure includes all permutations of the independent claims with their dependent claims. Moreover, additional embodiments capable of derivation from the independent and dependent claims that follow are also expressly incorporated into the present written description. These additional embodiments are determined by replacing the dependency of a given dependent claim with the phrase “any of the claims beginning with claim [x] and ending with the claim that immediately precedes this one,” where the bracketed term “[x]” is replaced with the number of the most recently recited independent claim. For example, for the first claim set that begins with independent claim 1, claim 4 can depend from either of claims 1 and 3, with these separate dependencies yielding two distinct embodiments; claim 5 can depend from any one of claim 1, 3, or 4, with these separate dependencies yielding three distinct embodiments; claim 6 can depend from any one of claim 1, 3, 4, or 5, with these separate dependencies yielding four distinct embodiments; and so on.

Recitation in the claims of the term “first” with respect to a feature or element does not necessarily imply the existence of a second or additional such feature or element. Elements specifically recited in means-plus-function format, if any, are intended to be construed to cover the corresponding structure, material, or acts described herein and equivalents thereof in accordance with 35 U.S.C. § 112(f). Embodiments of the invention in which an exclusive property or privilege is claimed are defined as follows.

1. An x-ray detector, comprising:
a housing including a front plate;
a substrate including a plurality of sensors configured to generate a two-dimensional image; and
an x-ray conversion material;
wherein the substrate and the x-ray conversion material are disposed within the housing and on the front plate.

2. The x-ray detector of claim 1, wherein:
the substrate is disposed on the front plate; and
the x-ray conversion material is disposed on the substrate or is part of the substrate.

3. The x-ray detector of claim 1, wherein:
the x-ray conversion material is disposed on the front plate; and
the substrate is disposed on the x-ray conversion material.

4. The x-ray detector of claim 1, further comprising:
an anti-scatter shield wherein the substrate and the x-ray conversion material are disposed between the front plate and the anti-scatter shield.

5. The x-ray detector of claim 1, further comprising:
a printed circuit board attached to the front plate by a structure including the substrate.

6. The x-ray detector of claim 5, further comprising:
compressible material disposed between the printed circuit board and a side of the housing opposite to the front plate.

7. The x-ray detector of claim 5, wherein:
the printed circuit board is attached to the front plate by the structure including the substrate with a releasable adhesive.

8. The x-ray detector of claim 1, further comprising:
a printed circuit board disposed on a side of the housing opposite to the front plate.

9. The x-ray detector of claim 1, further comprising:
a printed circuit board; and
a flexible electric circuit electrically coupling the printed circuit board to the substrate.

10. The x-ray detector of claim 9, wherein:
the substrate includes a planar portion extending beyond a perimeter of the printed circuit board, wherein the substrate is substantially planar; and
the substrate is electrically connected to the flexible electric circuit by the planar portion extending beyond the perimeter of the printed circuit board.

11. The x-ray detector of claim 1, wherein:
at least one wall of the housing other than the front plate if formed of plastic.

12. The x-ray detector of claim 1, further comprising:
a conductive layer disposed on a same side of the substrate as the front plate.

13. The x-ray detector of claim 1, further comprising:
an optically absorptive layer disposed on a side of the x-ray conversion material opposite to the substrate.

14. A method, comprising:
providing a front plate of a housing;
attaching a substrate including a plurality of sensors configured to generate a two-dimensional image to the front plate;
attaching an x-ray conversion material to the front plate; and
attaching the front plate to a remainder of the housing.

15. The method of claim 14, further comprising:
attaching an anti-scatter shield to the front plate such that the substrate and the x-ray conversion material are between the front plate and the anti-scatter shield.

16. The method of claim 14, wherein:
attaching the x-ray conversion material to the front plate comprises attaching the x-ray conversion material to the substrate; or
attaching the substrate to the front plate comprises attaching the substrate to the x-ray conversion material.

17. The method of claim 14, further comprising at least one of:
attach an optically absorptive layer on a side of the x-ray conversion material opposite to the substrate; and
attach a conductive layer on a same side of the substrate as the front plate.

18. The method of claim 16, further comprising:
attaching a printed circuit board to a side of the housing opposite to the front plate; or
attaching the printed circuit board to the front plate such that the substrate and the x-ray conversion material are between the front plate and the printed circuit board.

19. An x-ray detector, comprising:
means for converting x-rays into a two-dimensional image;
means for enclosing the means for converting the x-rays into the two-dimensional image; and
means for supporting the means for converting the x-rays into the two-dimensional image on a front of the means for enclosing the means for converting the x-rays into the two-dimensional image.

20. The x-ray detector of claim 19, further comprising at least one of:
means for reducing scatter of x-rays passing through the means for converting the x-rays into the two-dimensional image; and
means for absorbing light from the means for converting the x-rays into the two-dimensional image.
